(19) United States
(12) Patent Application Publication
(10) Pub. No.: US 2002/0096675 A1
(43) Pub. Date: Jul. 25, 2002

(54) Intersubband optical devices that operate at wavelengths shorter than 1.7 um

(76) Inventors: Alfred Yi Cho, Summit, NJ (US); Sung-Nee George Chu, Murray Hill, NJ (US); Claire F. Gmachl, New Providence, NJ (US); Hock Min Ng, New Providence, NJ (US)

Correspondence Address: Michael J. Urbano, 1445 Princeton Drive, Bethlehem, PA, 18017-9166, US

(21) Appl. No.: 09/949,096

(22) Filed: Sep. 7, 2001

Related U.S. Application Data
(60) Provisional application No. 60/249,078, filed on Nov. 15, 2000.
(60) Provisional application No. 60/313,403, filed on Aug. 17, 2001.

(51) Int. Cl. H01L 29/06; H01L 31/0328

(52) U.S. Cl. 257/25

(57) ABSTRACT

An intersubband (ISB) optical device comprises first quantum well (QW) interior regions having upper and lower energy states between which ISB transitions take place; and superlattice (SL) barrier regions interposed between the first QW interior regions. The SL barrier regions include second barriers and second QW interior regions, with the second QW interior regions being interposed between the second barrier regions. The first QW interior regions and the SL barrier regions are configured to produce an energy gap between the upper and lower states that is larger than the energy of a 1.7 μm wavelength photon. In accordance with another aspect of our invention, an intersubband optical device comprises a core region that includes a multiplicity of repeat units (RUs), each RU including a first barrier region and a QW active region disposed adjacent thereto, characterized in that (1) each of the QWs has upper and lower energy states separated by an energy greater than that of a 1.7 μm wavelength photon, (2) each of the first barrier regions comprises a SL, and (3) each SL is configured to have minibands and minigaps that provide for confinement of electrons in the upper state of the active QW. In a preferred embodiment, the SL first barrier region comprises second QW regions interleaved with second barrier regions, and the SL barrier region is doped only in the second QW regions, which are configured so that electrons therein tunnel into the first QW regions. In another embodiment, the device is formed on a lattice-mismatched substrate and a transition zone, that includes a strain-altering buffer region and a dislocation-reducing template region, is disposed between the substrate and the core region. One effect of the transition zone is to redistribute charge accumulated at the interfaces between the QW active regions and the first barrier regions.

### CROSS-REFERENCE TO RELATED APPLICATIONS

This application claims priority from provisional application Serial No. 60/249,078 entitled Quantum Well Stacks that Absorb at Wavelengths Shorter than 1.7 μm filed on Nov. 15, 2000 and provisional application Serial No. 60/313,403 entitled Optical Devices with Heavily Doped and Coupled Quantum Wells (Cho-Gmachl-Ng 108-22-4) filed on Aug. 17, 2001.

### FIELD OF THE INVENTION

This invention relates generally to optical devices that absorb and/or emit radiation in selected wavelength ranges and, more particularly, to intersubband (ISB) optical devices that operate at wavelengths shorter than about 1.7 μm.

### BACKGROUND OF THE INVENTION

Optical materials that emit or absorb radiation in selected wavelength ranges find application in a variety of optical devices including light emitters (e.g., LEDs and lasers), photodetectors (e.g., photodiodes, photoconductors, and solar cells), optical switches and optical amplifiers etc.

Of particular interest is a class of ISB optical devices that can function as light emitters, photodetectors or optical amplifiers. Focusing for the moment on ISB light emitters, we note that the realization of InGaAs/AlGaAs quantum cascade (QC) lasers in the mid-infrared (IR) wavelength range (˜4-20 μm) has prompted the search for a materials system that enables ISB transitions in the near-IR, especially at 1.3 μm and 1.55 μm, wavelengths of significant technological importance in telecommunications applications.

The principal limitation to realizing QC and other ISB lasers at wavelengths shorter than 1.7 μm is the insufficient conduction band offset available in most materials systems. When the offset is too small and the thickness of the quantum wells (QWs) is decreased to increase the energy (and hence decrease the corresponding wavelength) between the upper and lower laser levels, the upper laser levels may be squeezed out of the QWs into the continuum, where they are no longer confined. For example, in the InGaAs/AlGaAs materials system lattice-matched to InP, the conduction band offset is only about 500 meV, whereas for operation at about 1.55 μm the upper and lower lasing levels must be separated by at least about 800 meV at the operating temperature of the device.

One approach to this problem is to use the GaN/AlₓGa₁₋ₓN materials system, which has a conduction band offset as high as 2000 meV (for x=1). For example, Suzuki et al., Jpn. J Appl. Phys., Vol. 38, No. 2 (1999), have reported ISB absorption at wavelengths of about 3 μm in ISB optical devices having GaN QWs and bulk-like AlGaN barriers. To date, however, no one has realized the potential of this materials system for ISB transitions at the technologically important wavelengths less than about 1.7 μm.

From a processing standpoint, the prior art has been limited by the lack of a lattice-matched substrate on which to epitaxially grow the GaN/AlGaN devices, and growth on a lattice-mismatched substrate (e.g., sapphire) results in a large density of dislocations that thread through the epitaxial layers and hence provide many shunt paths for leakage current (in electrically pumped lasers). Furthermore, for ISB transitions at these shorter wavelengths the QWs have to be about 5-6 monolayers thick (13-15.5 A for GaN), which means that precise control of the growth conditions is required. And finally, in order to get the desired conduction band offset, the AlₓGa₁₋ₓN barriers must contain a relatively high mole fraction of AIN (e.g., x>0.65), but such AlGaN layers are extremely difficult to dope. For example, when AlₓGa₁₋ₓN is doped with Si, the number of free electrons is less than that required for laser operation (these electrons are supposed to be transported into the QWs where they would undergo radiative transitions) when the AlN mole fraction is greater than only about 0.15. Moreover, the number of free electrons is negligible when the Al content is above 0.65).

From a design standpoint, the lattice-mismatch also introduces strain in the crystal structure, which deforms the crystal lattice of the epitaxial layers. This strain, in turn, causes charge to be trapped at the interfaces between the GaN QWs and their AlGaN barriers. The trapped charges alter the conduction band profile (i.e., the shape of the QW) and distort the wavefunctions of the confined states in such a way that electrons in the upper lasing states can tunnel through the barriers and into the continuum, thereby reducing the population inversion.

Although the foregoing problems have discussed in the context of short wavelength ISB lasers, many are of concern in other ISB optical devices as well.

Therefore, a need remains in the ISB optical device art for a device that operates at wavelengths less than about 1.7 μm.

### SUMMARY OF THE INVENTION

In accordance with one aspect of our invention, an ISB optical device comprises first quantum well (QW) interior regions having upper and lower energy states between which ISB transitions take place; and superlattice (SL) barrier regions interposed between the first QW interior regions. The SL barrier regions include second barriers and second QW interior regions, with the second QW interior regions being interposed between the second barrier regions. The first QW interior regions and the SL barrier regions are configured to produce an energy gap between upper and lower states that is larger than the energy of a 1.7 μm wavelength photon.

In accordance with another aspect of our invention, an intersubband optical device comprises a core region that includes a multiplicity of repeat units (RUs), each RU including a first barrier region and a QW active region disposed adjacent thereto, characterized in that (1) each of the QWs has upper and lower energy states separated by an energy greater than that of a 1.7 μm wavelength photon, (2) each of the first barrier regions comprises a SL, and (3) each SL is configured to have mimbands and minigaps that provide for confinement of electrons in the upper state of the active QW. In a preferred embodiment, the SL first barrier region comprises second QW regions interleaved with second barrier regions, and the SL barrier region is doped only in the second QW regions, which are configured so that electrons therein tunnel into the first QW regions. In another embodiment, the device is formed on a lattice-mismatched substrate and a transition zone, that includes a strain-altering buffer region and a dislocation-reducing template region, is disposed between the substrate and the core region. One effect of the transition zone is to redistribute charge accumulated at the interfaces between the QW active regions and the first barrier regions.

### BRIEF DESCRIPTION OF THE DRAWINGS

Our invention, together with its various features and advantages, can be readily understood from the following more detailed description taken in conjunction with the accompanying drawing, in which:

FIG. 1A is a schematic view of a multilayered structure, or stack, that forms a part of the core region of ISB optical device in accordance with one embodiment of our invention;

FIG. 1B is a schematic conduction band diagram of the core region of FIG. 1A;

FIG. 2 is a schematic view of a portion of an ISB optical device showing how the core region of FIG. 1 is fabricated on a strain-relieving buffer layer and a lattice-mismatched substrate;

FIG. 3 is a schematic view of an ISB optical detector in accordance with another embodiment of our invention;

FIG. 4 is a schematic view of an electrically pumped ISB optical emitter in accordance with yet another embodiment of our invention;

FIG. 5 is a schematic view of an optically pumped ISB optical emitter in accordance with one more embodiment of our invention,

FIG. 6 shows normalized intersubband absorption spectra of three samples containing 11 Å (dashed curve), 12 Å (solid curve), and 13 Å (dashed-dotted curve) wide GaN multiple quantum wells (MQW). The barrier material was Al_{0.85}Ga_{0.15}N, and the structures were grown on an Al_{0.65}Ga_{0.35}N buffer layer. The inset shows the conduction band profile and moduli squared of the electron wavefunctions of a 13 Å wide GaN QW calculated by self-consistently solving Poisson's and Schroedinger's equation for a doping level in the QW of b 1×10²⁰ cm⁻³ (solid curve) and for an undoped QW (dashed curve). The open arrow indicates the absorption process;

FIG. 7 shows a transmission electron microscope (TEM) image of a portion of a GaN MQW structure with superlattice (SL) barriers in accordance with one aspect of our invention. Light gray layers indicate Al_{0.65}Ga_{0.35}N, dark gray layers GaN.

FIGS. 8A to 8E show schematic conduction band profiles of the core region of several samples to illustrative various ways that the core region may be doped in accordance with a number of embodiments of our invention The doped areas are shown crosshatched;

FIG. 9 shows conduction band profiles and moduli squared of the electron wavefunctions calculated for the core region of an ISB device having a 16 Å wide GaN active region QWs with SL barriers. The calculations were made by self-consistently solving Poisson's and Schroedinger's equation for a doping level of ˜1×10²⁰ cm⁻³. The superlattices comprised 10 Å wide Al_{0.65}Ga_{0.35}N barriers and 6-7 Å wide GaN QWs. The horizontal gray bars indicate the doped portion of the core region. The open arrow indicates the absorption process. FIG. 9(a) shows the case where the active region QW is doped, and FIG. 9(b) shows a selectively doped structure in which only the SL QWs immediately adjacent the active QW are doped. The letters “A” and “B” in FIG. 9(b) indicate SL barriers in which the electric field is enhanced and decreased, respectively, by the space charge induced by electron transfer from the SL regions into the main QW. The arrow labeled “z” indicates the growth direction;

FIG. 10 shows intersubband absorption spectra of three samples containing 13 Å wide GaN QWs embedded in SL barriers. Sample N273 was doped in the active QWs, but Samples N277 and N278 were selectively doped in certain ones of the SL QWs. Solid curves are measured data, dashed lines are Gaussian curves fitted to the data. The full width at half maximum (FWHM) values of the absorption features are given. The residual waviness in the spectrum of sample N278 is a result of its very thick (6.9 μm) GaN buffer layer. Samples N273 and N277 had GaN buffer layers less than 1 μm thick;

FIG. 11 is a cross-sectional TEM image showing the reduction of threading dislocation density after the deposition of LT-AIN layers on a sapphire substrate. The LT-AIN layers are indicated by arrows. Screw and mixed dislocations are visible under this imaging condition;

FIG. 12 shows the oscillation of the pyrometer signal as a function of time. Each oscillation corresponds to a GaN thickness of about 200 nm The growth rate in this case was close to 0.2 μ/h;

FIG. 13 is cross-sectional TEM image of a sample with four GaN QWs (10, 20, 30 and 40 Å) with Al_{0.8}Ga_{0.2}N barriers;

FIG. 14 shows photoluminescence of 10, 20, 30 and 40 Å GaN QWs with Al_{0.2}Ga_{0.8}N barriers grown on a thick (0.6 μm) GaN buffer layer;

FIG. 15 is a cross-sectional TEM image of a 10-period GaN/Al_{0.65}Ga_{0.35}N SL for measuring ISB transitions. The SL was grown on a 0.6 μm GaN layer. The GaN QWs (dark layers) and the AlGaN barriers (lighter layers) were 20 and 60 Å wide, respectively.

FIG. 16 shows ISB absorption at 1.52 um for a sample with 13 A wide GaN QWs and 60 Å wide Al_{0.85}Ga_{0.15}N barriers (10 periods);

FIG. 17 shows the dependence of ISB absorption wavelength as a function of GaN QW width. The various symbols represent samples with different AlₓGa₁₋ₓN composition in the barriers (open circle: x=0.45; solid squares and open triangle: x=0.65; solid circles: x=0.80; open square and solid triangle: x=0.85). All SLs were grown on thick Al_{0.5}Ga_{0.5}N (open triangle) or Al_{0.65}Ga_{0.35}N (solid triangle) template layers and an AlN buffer layer;

FIG. 18 shows a measured intersubband absorption spectrum of sample N306 (solid black curve V), a sample containing symmetric double quantum wells (DQWs). The least square fit curve I (long dashes) is a sum of two Lorentzian lineshape functions. The individual Lorentzians are depicted by curves II & III (short dashes). The solid gray line (curve IV) is the fit to the data using only a single Lorentzian. The inset shows a schematic conduction band profile (the coordinates are energy “E” versus growth direction “z”) and the moduli squared of the electron wavefunctions of the symmetric 12/10/12 Å GaN/AlGaN DQW structure (See Table 1, infra). The energy levels involved in the optical transitions (block arrows) are numbered 1-4;

FIG. 19(a) shows the conduction band profile and moduli squared of the electron wavefunctions calculated for an asymmetric 15/7/20 Å GaN/AlGaN DQW structure with doped SL barriers by self-consistently solving Poisson's and Schroedinger's equations for an effective doping level of ˜2×10¹⁹ cm⁻³. The SLs were modeled with 15 Å wide Al_{0.65}Ga_{0.35}N barriers and 8 Å wide GaN QWs. The energy levels involved in the optical transitions (block arrows) are numbered 1-4. The letter “z” indicates the growth direction FIG. 19(b) shows measured intersubband absorption spectra of samples N366, N362, N369, and N378 (top-to-bottom, solid lines) and their respective least square fit curves (dashed curves), sums of two Lorentzian lineshape functions. The barrier thicknesses of the DQWs are indicated as being 7, 10 and 15 Å. Sample N378, marked “rev.”, was grown under modified conditions leading to thinner layers and accordingly shorter peak absorption wavelengths;

FIG. 20 shows measured ISB absorption spectra of samples N326 and N325, (top-to-bottom, solid line curves) and their respective least square fit curves (long dash curves), sums of two Lorentzian lineshape functions. The individual Lorentzians are shown as short dash curves. The measured data have been offset by +0.05 from their respective fit curves; and N326 is in its entirety offset from N325. The barrier thicknesses of the DQWs are indicated as 10 and 60 Å.

FIG. 21 shows full width at half maximum (FWHM) values versus peak transition energies for all transitions observed in Example III, infra. The numerical values have been extracted from the least square fits as shown in FIGS. 18-20. Transitions into the lower-lying state “3” are grouped by ellipsoids I & II, transitions into the higher-lying level “4” are grouped by ellipsoids III & IV. Gray circles indicate the asymmetric DQWs of FIG. 19 having x˜0.65 AlₓGa₁₋ₓN-mole fraction barriers; these devices exhibited line broadening when the transition is into level 4 as compared to level 3, which is illustrated by the oblique arrow between ellipsoid I (level 3 transitions having lower FWHMs) and ellipsoid III (level 4 transitions having higher FWHMs). Solid squares denote the asymmetric DQWs of FIG. 20, and the solid triangles indicate the symmetric DQW of FIG. 18. The latter two employ x˜0.90 ALₓGa₁₋ₓN-mole fraction barriers, and in both cases the horizontal arrows indicate no line broadening for transitions into the higher level 4. A plot of the FWHM value as a percentage of the peak transition energy versus the latter yielded a qualitatively very similar picture.

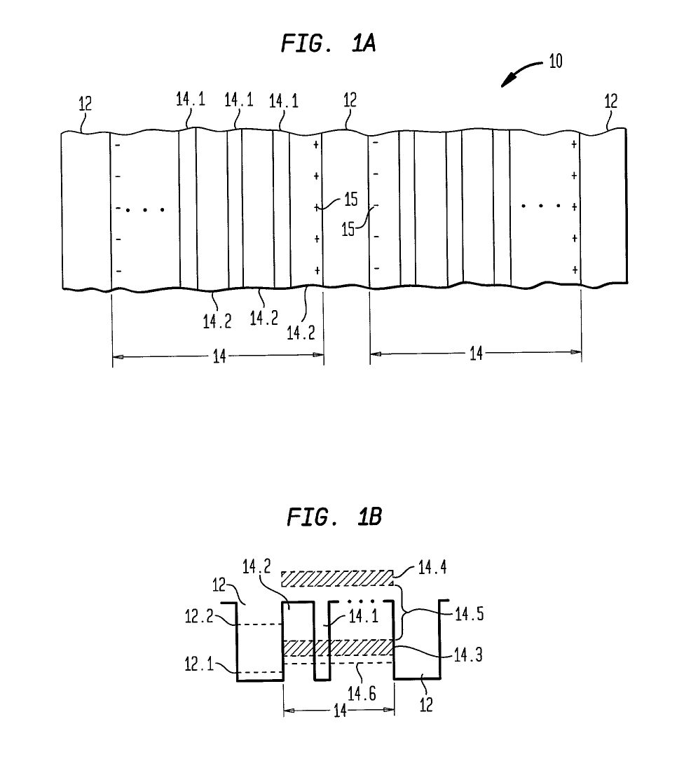

In the interest of clarity and simplicity, the FIGS. 1-5 & 8 have not been drawn to scale. In addition, when describing physical or optical dimensions, the symbol A stands for Angstroms, whereas when describing electric current, it stands for Amperes.

### DETAILED DESCRIPTION OF THE INVENTION

### General Discussion

With reference now to FIGS. 1A & 1B, we show a portion of the core region 10 of an ISB optical device, the core region including a multiplicity of repeat units (RUs) each of which comprises first interior or active regions 12 and an adjacent principal barrier regions 14. When viewing the stack of RUs as a whole, the active regions are located between a pair of barrier regions. The active regions include at least one quantum well (hereinafter referred to as an AR QW); e.g., a single QW or multiple, coupled QWs, in which radiative ISB transitions (absorption or emission) take place when slutable energy is applied to the core region. As shown in FIG. 1B, these transitions take place between an upper energy level or state 12.2 and a lower state 12.1 both of which are confined in the AR QW. In accordance with one aspect of our invention, each principal barrier region comprises a superlattice (SL), which includes second interior QW regions 14.1 (hereinafter referred to as the SL QWs) separated from one another by second barrier regions 14.2. The AR QWs and the SL principal barrier regions are configured to produce an energy gap or separation between upper confined state 12.2 and lower confined state 12.1 that is larger than the energy of a 1.7 μm wavelength photon.

As discussed earlier, if the lattice of the core region layers is strained (e.g., by growth on a lattice mismatched substrate), charge 15 (FIG. 1) may accumulate at the interfaces between the AR QWs and adjacent layers of the barrier regions 14. In conventional ISB devices, the electric field from this charge may be sufficiently strong to distort the conduction band profile and the wavefunctions of the confined electron states so that electrons tunnel out of the upper level of the AR QWs into the barrier regions, thereby degrading device performance. To address this problem our barrier regions are configured as SLs that produce upper and lower minibands 14.4 and 14.3 separated by a minigap 14.5 that serves to confine electrons in the upper energy states 12.2 ofthe AR QWs.

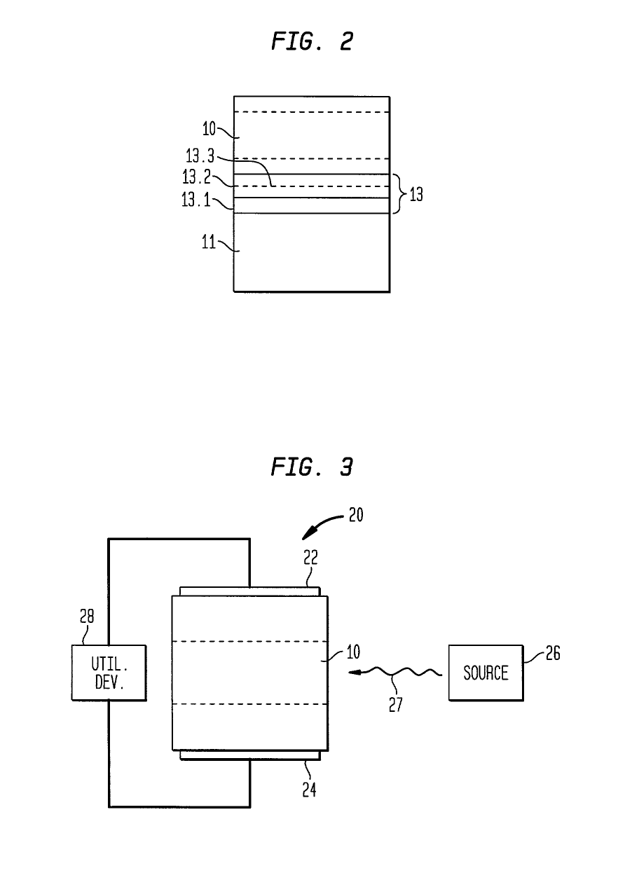

In addition, as shown in FIG. 2, the core region 10 is grown on a transition zone 13 that is first formed on the lattice-mismatched substrate 11. Transition zone 13 includes a buffer region 13.1 formed on substrate 11 and a template region 13.2 formed on buffer region 13.1. The buffer region serves both as a nucleation layer for growth of the core region 10 and as a strain-relieving layer; that is, it relieves most of the strain caused by the lattice mismatch between substrate 11 and the epitaxial layers grown thereon. On the other hand, template region 13.2 also alters the strain in the core region depending on the materials used to fabricate it. For example, when the template region and the core region QWs are the same material, the QWs will be lattice matched, but the core region barriers may be under tensile strain. Conversely, when the template region and the core region barriers are the same material, the barriers will be lattice matched, but the core region QWs may be under compressive strain. In either case, the template region serves to redistribute charge accumulated at the AR QW interfaces, preferably so that the built-in electric field is decreased in the barriers and increased in the AR QWs. In addition, template region 13 also includes a dislocation-reducing region 13.3 that serves to reduce threading dislocations in the device. Region 13.3 comprises at least two, thin, separated layers of material that are embedded in template region 13 and that have a lower in-plane lattice constant than the surrounding material of region 13.

The energy of a 1.7 μm photon is about 730 meV, which means that conduction band offset of the materials used to fabricate an ISB device for operation at 1.7 μm must be greater than about 730 meV. Similarly, for the device to operate at 1.55 μm, a wavelength of particular significance in telecommunications applications, the conduction band offset must be greater than about 800 meV. A preferred materials system that provides the requisite band offset is GaN/AlGaN, where the QWs 12 and 14.1 would comprise GaN (or AlGaN with less than about 0.05 mole fraction of AlN), and the second barrier regions 14.1 would comprise AlGaN with greater than about 0.65 mole fraction of AlN. This materials system is commonly grown epitaxially on a lattice-mismatched (0001) sapphire substrate 11 (FIG. 2). In this case, the substrate is first coated with a relatively thick (e.g., 1.0-7.0 μm) transition zone 13, as described above. In the GaN/AlGaN materials system, buffer region 13.1 illustratively comprises a relatively thin (e.g., 10-30 mn) AlN region that is grown at a relatively high growth temperature (e.g., 700-730° C. for MBE growth), the bulk of template region 13.2 comprises a relatively thick (e.g., 0.5-1.0 μm) GaN or AlGaN region also grown at a relatively high growth temperature (e.g., 700-730° C. for MBE growth), and dislocation-reducing region 13.2 comprises a pair of thin (e.g., 50-100 A) AlN layers grown at a relatively low growth temperature (e.g., 400-450° C. for MBE growth). These two layers are typically separated from one another by about 60-150 nm of GaN or AlGaN.

Regardless of the materials system used, we prefer that the AR QWs be wider than the SL QWs. For example, it is suitable for the AR QWs 12 to be at least 1.5 (e.g., 2.0 or 2.5) times as wide as the SL QWs 14.1. Illustratively, the AR QWs are about 6 monolayers wide and the SL QWs are about 3 monolayers wide, where a monolayer is about 2.6 Å thick. In this case the second barrier regions might be 6 monolayers thick Alternatively, the AR QWs maybe 5 monolayers wide and the SL QWs 2 monolayers wide. In this case the second barrier regions might be 5 monolayers thick. Other combinations of QW and barrier thickness are, of course, within the scope of our invention.

Doping of the various layers of the core region is preferably n-type, but not all layers need be doped. For example, only the AR QWs may be doped as shown in FIG. 8A, or all of the SL QWs may be doped as shown in FIG. 8B, or only one of the second barriers on either side of all of the AR QWs may be doped as shown in FIGS. 8C and 8D, or both second barriers on both sides of each AR QW may be doped as shown in FIG. 8E. In any case suitable doping levels are in the range of about 0.1-10×10²⁰ cm⁻³. The choice among these alternatives may be influenced by the materials system and the ability or inability to effectively dope certain materials within the system. For example, it is extremely difficult to dope AlGaN when the mole fraction of AN exceeds about 0.2; e.g, an insignificant number of free electrons is produced when such material is doped with Si. This limitation is significant since bulk-like AlGaN is the wide bandgap barrier material of choice in conventional short wavelength ISB devices for connning the states of the narrower bandgap GaN QWs, and most designs dope the barrier rather than the QW in order to reduce impurity scattering and the associated line broadening. In accordance with another aspect of our invention, this limitation is addressed by doping only the GaN SL QWs 14.1, and by making the SL barriers 14.2 sufficiently thin that electrons are transported (i.e., tunnel) from the SL QWs into the AR QWs.

In this type of design, the Fermi level 14.6 in each SL barrier 14 should preferably be located below the bottom of the lowest confined miniband 14.3 and above the lower state 12.1 of the AR QW, as shown in FIG lB. This design assures that essentially all electrons will be transferred (via tunneling) from the doped SL QWs into the AR QWs. In the case where the ISB device functions in an absorption mode (e.g., as a photodetector or an optically pumped emitter), positioning the Fermi level in this fashion (as contrasted with locating the Fermi level within the lower miniband 14.3) increases the AR QW absorption and insures that there will be no spurious absorption signal from the SL barriers (i.e. electron transitions between the lower and upper minibands 14.3 and 14.4, respectively).

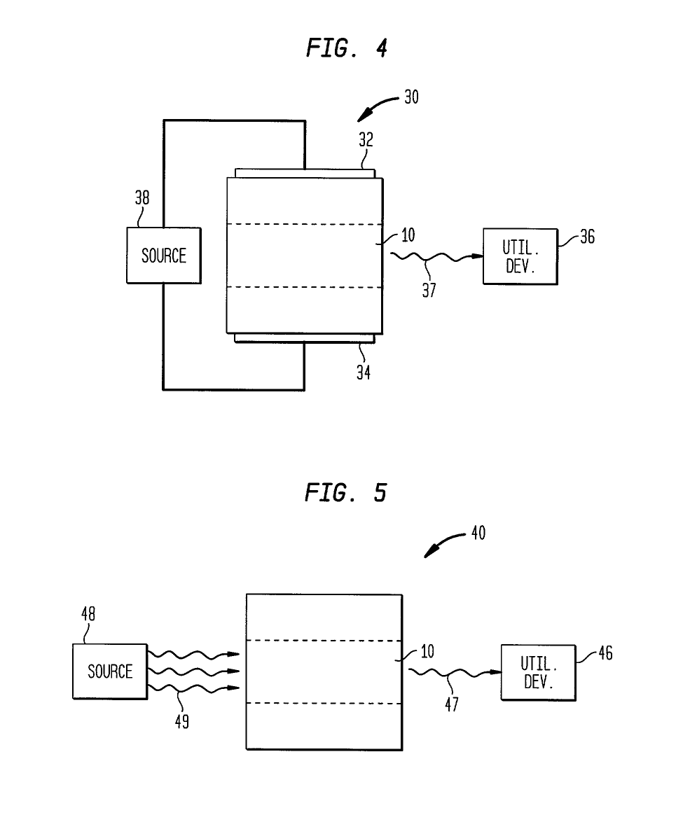

Various ISB optical devices can be implemented utilizing the principles of our invention including a photodetector apparatus (FIG. 3), an electrically pumped emitter apparatus (FIG. 4) and an optically pumped emitter apparatus (FIG. 5). More specifically, the photodetector apparatus of FIG. 3 includes an ISB optical device 20 that includes a core region 10 of the type described with reference to FIG. 1, electrodes 22 and 24 on the device, and a utilization device 28 electrically coupled across the electrodes. A source 26 emits optical radiation 27 at a wavelength less than 1.7 ,μm, and that radiation is optically coupled (e.g., via lens means not shown) into core region 10. The radiation 27 is absorbed in the core region and induces ISB transitions therein, resulting in a photocurrent that flows to utilization device 28 via electrodes 22 and 24. Conversely, the electrically pumped emitter of FIG. 4 comprises an ISB optical device 30 that includes a core region 10 of the type described with reference to FIG. 1, electrodes 32 and 34 on the device, and an electrical source 38 electrically coupled across the electrodes. Source 38 supplies pumping current to the core region 10, which undergoes radiative ISB transitions and thereby emits optical radiation 37 at a wavelength less than 1.7 μm Radiation 37 is optically coupled (e.g., via lens means not shown) to a utilization device 36 (e.g., a photodetector, a receiver, an optical fiber, an optical amplifier, etc.). Finally, the optically pumped emitter of FIG. 5 includes an ISB optical device 40 that includes a core region 10 of the type described with reference to FIG. 1, and an optical source 48 optically coupled (e.g., via lens means not shown) to core region 10. Source 48 supplies optical pump signal 49 to the core region 10, which absorbs the pump signal and undergoes radiative ISB transitions, thereby emitting optical radiation 47 at a wavelength less than 1.7 μm. Radiation 47 is optically coupled (e.g., via lens means not shown) to a utilization device 46 (e.g., a photodetector, a receiver, an optical fiber, an optical amplifer, etc.).

The following examples describe GaN/AlGaN ISB optical devices in accordance with various embodiments of our invention. Various materials, dimensions and operating conditions are provided by way of illustration only and, unless otherwise expressly stated, are not intended to limit the scope of the invention. As used herein, the term undoped means that a particular semiconductor layer or region is not intentionally doped; i.e., any doping of such a region or layer is relatively low and typically results from residual or background doping in the chamber used to grow the layers of the device.

### EXAMPLE I

In this example we first demonstrated ISB absorption in conventional multiquantum well (MQW) devices that had narrow GaN quantum wells and bulk-like AlₓGa₁₋ₓN barriers with relatively high, x=0.85, AlN-mole fraction. Absorption occurred at wavelengths as short as 1.41 μm and consistently around 1.55 μm, which is the first demonstration that ISB transitions in the telecommunications wavelength range can be achieved with Group-III nitride materials. However, this demonstration relied on the use of relatively high AlN mole-fraction AlGaN barrier material and growth on a strained, AlₓGa₁₋ₓN, x=0.65, AlN mole-fraction buffer layer. This use of high AlN mole fraction (x>0.65) barrier material may not be advisable for more complex devices due to the relatively large residual strain and crystal structure-induced giant piezo- and pyroelectric fields. Therefore, we improved the device by incorporating a design of the type described in conjunction with FIGS. 1, 2 and 3. This ISB absorption device included relatively thin GaN (a few Å) AR QWs 12 and 14.1 and GaN/AlGaN SL barrier regions 14. The latter were short period superlattices that included very thin (a few Å) GaN SL QWs and AlₓGa₁₋ₓN, x=0.65, SL barriers, which had less AlN, and hence lower barrier height, than the conventional samples mentioned above. Despite the lower barrier height, upper state confinement was restored by electron Bragg scattering, which occurred because the SL barriers were designed so that the minigap therein confined electrons to the upper AR QW state. We observed ISB absorption at wavelengths as short as 1.52 μm in such a structure. In addition, these SL barriers were selectively doped by introducing dopant atoms into only the SL QWs. The SL barriers were sufficiently thin that charge transfer of free carriers (electrons) took place into the AR QWs. This doping technique is important since there is no know technique for satisfactorily doping AlₓGa₁₋ₓN having relatively high mole fractions (values of x) of AlN. While open questions remain, we demonstrated the functionality of our approach in various configurations. As a result, we observed a clear narrowing of the absorption linewidth for ISB devices having selectively doped SL barriers versus conventional ISB devices in which the AR QWs are doped.

All samples were grown by molecular beam epitaxy (MBE) on c-axis sapphire and with different transition zone thicknesses and compositions. The buffer regions were AlN, and the template regions were either GaN or AlGaN. Details of the growth procedures, as well as a summary of material characterization results on many of the wafers of this study can be found in Example II. In order to minimize interference from multiple reflections at the interference between the transition zone and the sapphire substrate, the incidence angle of the p-polarized light (electric field vector normal to the QW plane) was adjusted to be close to the Brewster angle. As background spectra, transmission through a comparable-size, plain sapphire sample and s-polarized transmission spectra were used.

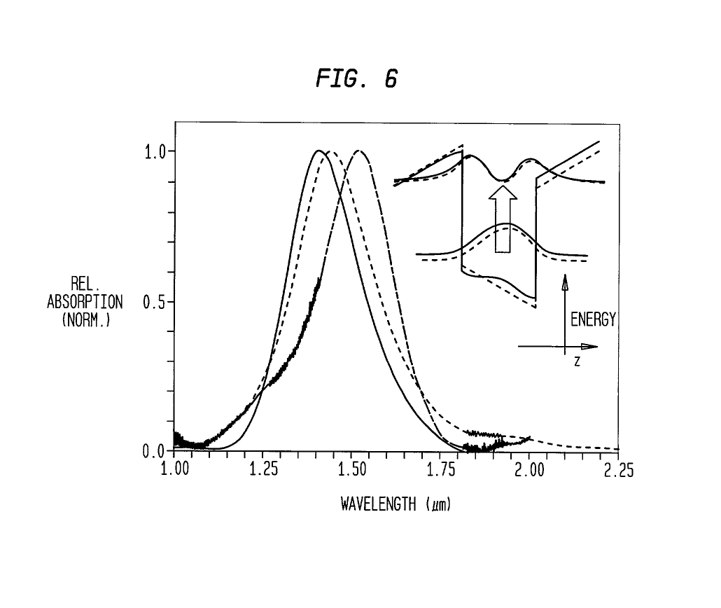

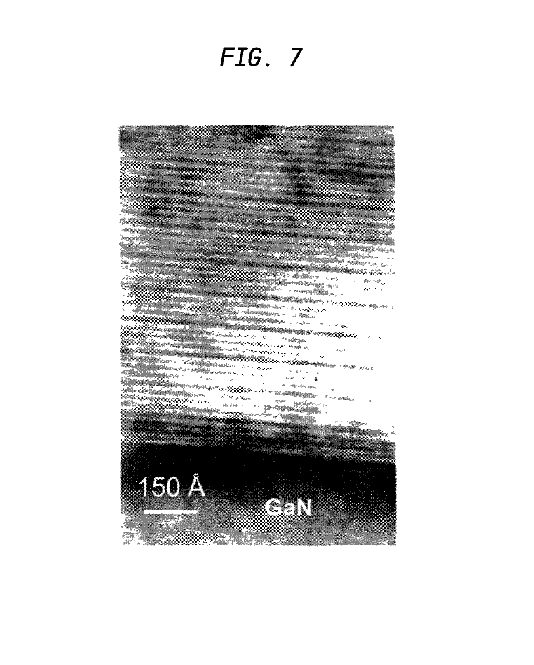

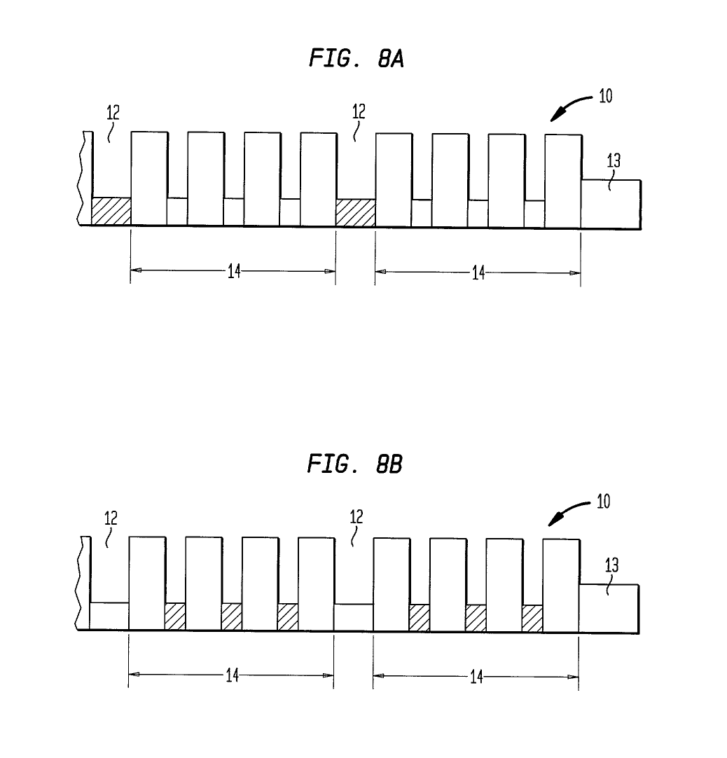

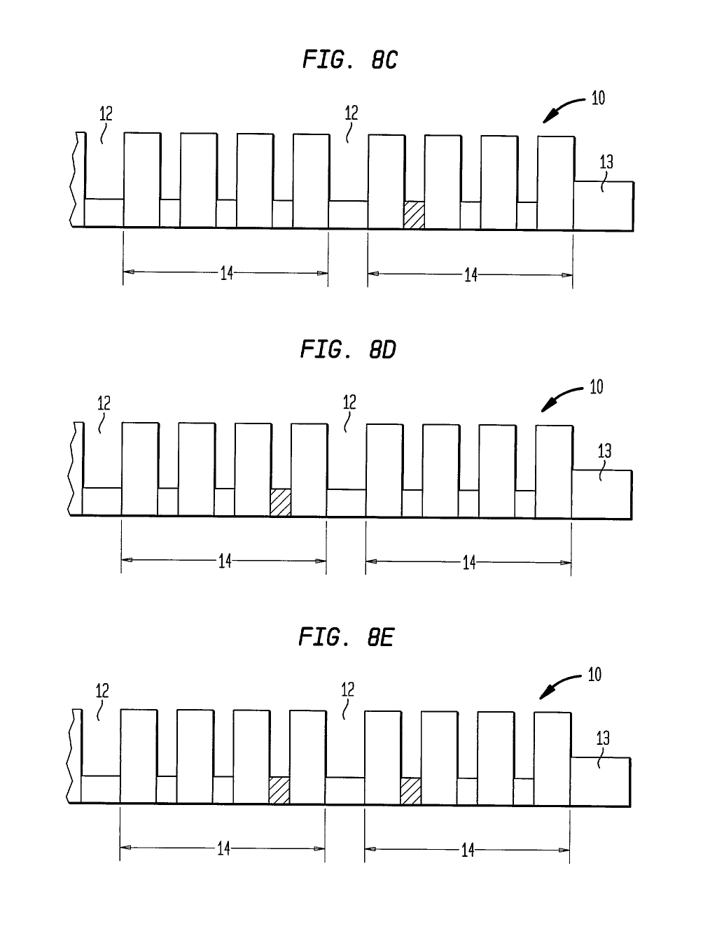

FIG. 6 shows ISB absorption spectra of three different conventional MQW samples, each containing 10 GaN QWs. In one sample the QWs were 11 Å wide, in the second they were 12 Å wide, and in the third 13 Å wide. The bulk-like Al_{0.85}Ga_{0.15}N barriers were 60 Å wide in all three samples. These MQW structures were grown on ˜0.5 μm thick Al_{0.65}Ga_{0.35}N buffer layers. The QWs were doped with Si to ˜1×10^{20 cm}⁻³, which resulted in Fermi level energies of 132, 144, and 156 meV, respectively, in the three devices. The inset in FIG. 6 shows a self-consistent calculation ofthe conduction band structure of a 13 Å wide QW of this doping level compared to an undoped QW, performed by iteratively solving Poisson's and Schroedinger's equations using widely accepted material parameters. The electric field in the wells and barriers was set to ±5 MV/cm. The ISB transition energy in a narrow QW is only a slowly varying function of those fields. It can be seen, that for the single, well-doped, narrow QW, even such a high doping level affects the ISB energy level structure, and with it the peak absorption wavelength, very little. In general, the transition energy is decreased with increasing doping level. The absorption curves of the main graph display ISB peak transition energies of 0.862, 0.882, and 0.817 eV (peak wavelengths of 1.44, 1.41, and 1.52 μm) for the 11, 12, and 13 Å wide GaN QWs, respectively. These results are in good agreement with the calculations; i.e. deviations are well within what is expected for single monolayer fluctuations. We also note that it is difficult to control the growth on the Å-level, which causes some fluctuations between the samples.

Next, we replaced the bulk-like barriers with SL barriers of the type described with reference to FIGS. 1, 2 and 3 in accordance with one aspect of our invention. Two sets of samples were grown and investigated. Each repeat unit (RU) of one set contained an absorbing AR QW of 13 Å wide GaN and SL barriers of four 5-Å wide SL QWs interleaved with 10 Å wide 0.65 AlN mole-fraction AlGaN barriers. In the other set each RU contained an absorbing AR QW of 16 Å wide GaN and SL barriers of three 8-Å wide SL QWs interleaved with 16 Å wide 0.65 AlN mole-fraction AlGaN barriers. All samples contained 15 nominally identical RUs of the AR QW and adjacent SL. Each device was formed on a GaN buffer layer on a sapphire substrate. FIG. 7 shows a TEM image of a structure in which each SL barrier contained 3 SL QWs. In each set, the RUs of different samples were doped differently as follows: (1) Samples N257 & N273 were doped inside only the AR QW to n ˜1×10²⁰ cm⁻³, as shown in FIG. 8A; Other samples were doped inside some or all of the SL QWs to the same level as in (1) above; for example, (2) Samples N272 & N278 were doped inside all SL QWs but not in the AR QWs, as shown in FIG. 8B; (3) Sample N277 was doped inside only one SL QW that immediately preceded (closer to the substrate) the AR QW, as shown in FIG. 8C; (4) Sample N279 was doped inside only one SL QW that immediately followed (farther from the substrate) the AR QW, as shown in FIG. 8D; and (5) Sample N281 was doped inside one SL QW that immediately preceded the AR QW and one SL QW that intermediately followed the AR QW, as shown in FIG. 8E.

In Samples N257, N271 and N272 the AR QWs and the SL barriers were each 6 monolayers thick, and the SL QWs were each 3 monolayers thick. In Samples N273, N277-279, and N281 the AR QWs were each 5 monolayers thick, the SL barriers were each 4 monolayers thick, and the SL QWs were each 2 monolayers thick.

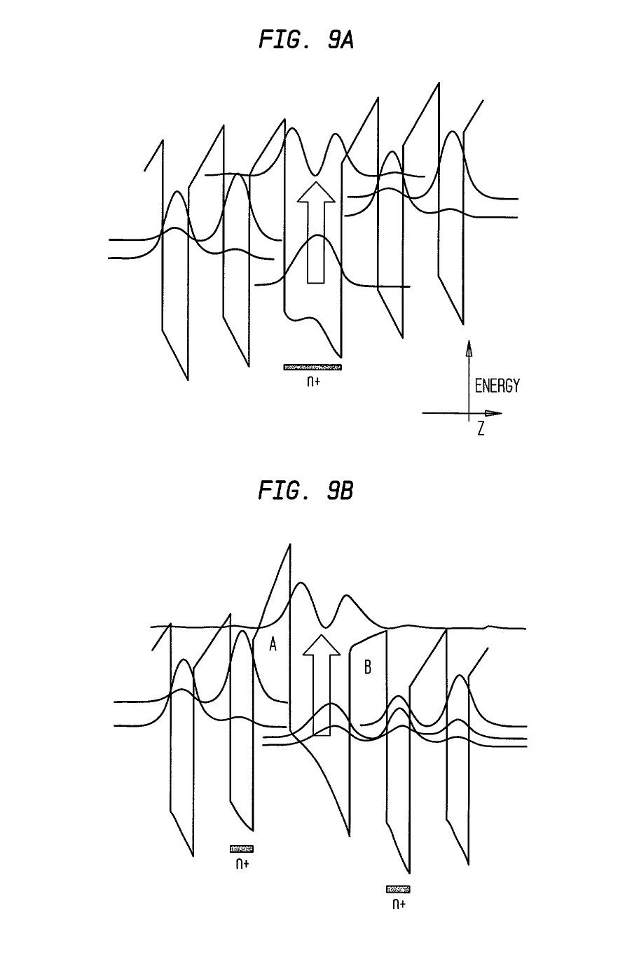

FIG. 9 shows two self-consistent calculations of the conduction band profile of one AR QW with half a SL barrier on each side. FIG. 9(a) shows the condition where the AR QW is doped; as in the conventional bulk barrier case, and only little band distortion can be seen from the doping, which is again a result of the narrow QW and the tightly confined electron wavefunctions. The latter allows only little charge transfer to screen the local electric fields (which have again been set to ±5 MV/cm). As shown in FIG. 9(b), however, if SL QWs are doped (e.g., only those adjacent to the AR QW, as shown in FIG. 8E), then electrons will transfer from the SL into the AR QW, resulting in space charge regions adding to the intrinsic electric field. Depending on the local polarity of the in-built electric field, the latter can either be strongly enhanced (FIG. 9(b), barrier A) or even cancelled (FIG. 9(b), barrier B). As self-consistent calculations showed, only about one third of the carriers was transferred into the AR QW. We would, however, like to point to several details: First, strong Bragg confinement is provided by the SL to the upper energy state of the AR QW (FIG. 9(b), to the right of barrier B); Secondly, absorption from the lower into the upper miniband of the SL would occur at wavelengths much shorter than 1 μm due to the very narrow SL QWs, and can therefore be ruled out in our measurements.

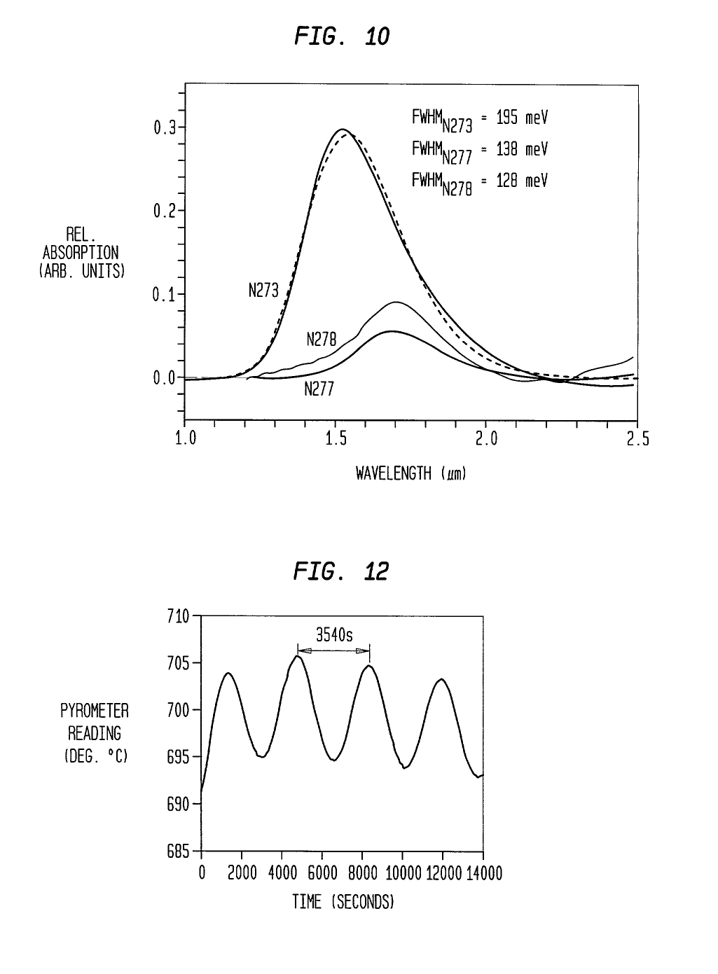

FIG. 10 shows measured absorption spectra of three samples of the first set having 13 Å wide AR QWs. As noted earlier, each RU was doped as follows: in Samples N273 only the AR QW was doped; in Samples N277 only the SL QW immediately preceding the AR QW was doped; and in Sample N278 all SL QWs were doped. Peak transition energies of 0.816, 0.734, and 0.730 eV (peak wavelengths of 1.52, 1.69, and 1.70 μm) for N273, N277, and N278 were measured, respectively. Sample N279, in which only the SL QW following the AR QW was doped, showed absorption peaked at 0.757 eV (1.64 μm). The smaller area under the curves of Samples N277, N278, compared with Sample N273 is likely caused by the smaller number of electrons that transferred into the AR QW from the selectively doped SL. Again, these results are in reasonable agreement with the calculations.

Finally, we consistently measured a narrower ISB absorption width (by >20%) for the samples in which the SLs were selectively doped compared to those in which the AR QWs were doped, even after compensating for the varying peak energies. This result is a generally expected feature of the selective doping scheme as impurity scattering is reduced, an effect which certainly contributes to the absorption linewidth due to the high doping level. As the absorption curves showed only little asymmetry, a strong contribution from the combination of the reduced carrier density in the QW and band non-parabolicity should be ruled out.

### EXAMPLE II

In this example we describe the growth of high quality GaN/AlGaN SLs by molecular beam epitaxy (MBE) in order to achieve ISB absorption at wavelengths around 1.55 μm. By varying the thickness of the GaN quantum wells and the composition of the AlGaN barrier regions, the ISB absorption peak was varied in the wavelength range of 1.52-4.2 μm. To the best of our knowledge, this is the first observation of ISB absorption at 1.52 μm for QWs based in the GaN/AIGaN materials system. Although the ISB devices of Example II did not include SL barrier regions, the processes described herein were also employed to fabricate the ISB devices of Examples I and II, which did contain SL barrier regions.

Experimental Procedure

### Molecular Beam Epitaxy

The GaN/AlGaN superlattice structures were deposited on (0001) sapphire substrates first coated with a thick AlN buffer layer and then thick GaN or AlGaN (0.5-0.8 μm) template layers. Growth was performed in a Riber 32 MBE system with active nitrogen supplied by passing high-purity nitrogen (99.9999%) through a radio frequency (RF) plasma source from EPI MBE Products Group. The elemental group-RI sources (Ga and Al) and silicon dopant were supplied by standard effusion cells. The sapphire substrate was back-coated with Ti to facilitate pyrometry and held in place with In-free sample holders. After outgassing in the preparation chamber, the substrate was transferred to the growth chamber and exposed to the nitrogen plasma for 30 minutes to nitridate the surface. Following the nitridation step, the AlN buffer layer was deposited at ˜720° C., and the growth of the epitaxial films proceeded at temperatures between 700 and 730° C. The growth temperature was monitored by a thermocouple located behind the substrate and also by an infrared pyrometer. The growth rates of GaN and AlGaN were monitored in-situ using pyrometric interferometry and were typically between 0.18-0.25 μm/h.

The initial stages of growth include two additional low-temperature AN (LT-AIN) layers (each 85 Å) grown at ˜420° C. with separation ranging from 60 to 150 nm between high-temperature grown GaN to block the propagation of threading dislocations. The GaN (or AlGaN) template layers were grown at 720° C. with a nominal thickness of 0.6 μm. Subsequently, the quantum wells for the intersubband absorption measurements were grown with either 10 or 30 periods, and the well thickness ranged from 10 to 30 Å. The GaN wells were uniformly doped with Si to a level between 7×10¹⁸ and 5×10^{19 cm}⁻³ in order to ensure electron population in the first conduction subband. The Al concentration in the barrier layers was varied between 45 and 85% while the barrier thickness was kept constant at 60 Å.

### Characterization Methods

Thick GaN layers and superlattice structures were examined by cross-sectional scanning electron microscopy (SEM) using a TOPCON field-emission electron microscope and cross-sectional transmission electron microscopy (TEM) using a Phillips 420 electron microscope operated at 120 kV. X-ray diffraction measurements were performed on a Bruker AXS diffractometer with a copper source. In order to calibrate the AlN mole fraction in the AlGaN barriers, a sample was grown starting with a 0.2 μm GaN layer followed by three AlₓGa₁₋ₓN layers (each about 0.2 μm thick) each with different compositions. The AlN mole fraction was estimated from the relative c-lattice constant with the assumption that Vegard's Law holds and that the AlGaN layers are relaxed. However, others have observed by x-ray reciprocal space mapping that Al_{0.1}Ga_{0.9}N grown on GaN was strained even with a thickness of 600 nm. Therefore, to obtain a more accurate value for the AN mole fraction, it would be necessary to determine both the a- and c-lattice parameters because of the deformation of the unit cell due to biaxial strain. The error in AlN mole fraction by assuming relaxed layers should be no larger than ±5% based on published studies that determined the Al mole fraction over the entire composition range using x-ray diffraction and elastic recoil detection analysis.

For photoluminescence measurements, a He-Cd laser was used as the excitation source. The intersubband absorption measurements were carried out with the samples placed inside a beam condenser in a Fourier Transform Infrared (FTIR) spectrometer. White light was directed through the sample in a multipass geometry and detected using a cooled InSb detector. A large area wire grid polarizer was used to select either p- or s-polarized light entering the sample.

Results and Discussion

### Reduction of Threading Dislocations

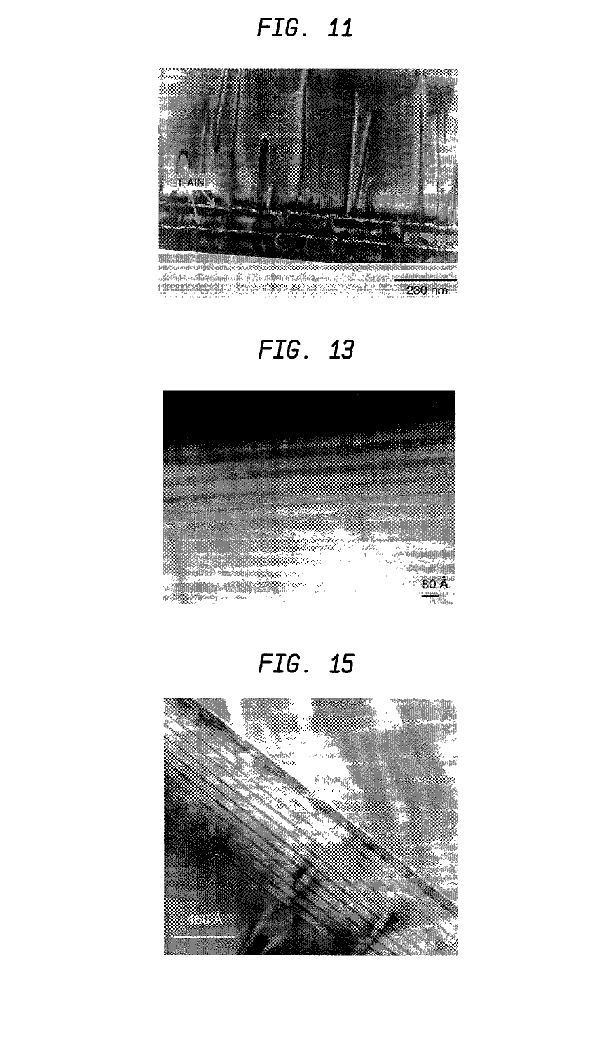

In order to achieve uniformity of the quantum well thickness, threading dislocations have to be reduced as much as possible in the region of the quantum wells because of thickness fluctuation in the vicinity of threading dislocations. Since heteroepitaxy is unavoidable, a number of prior art techniques have been applied for the reduction of threading dislocation density. Epitaxial lateral overgrowth (ELO) has been shown to be effective in reducing the threading dislocation density in metalorganic chemical vapor deposition (MOCVD) growth of GaN. However, the drawback of this technique is that it involves more complicated processing steps including SiO₂ deposition, patterning and then a second growth step. An alternative method is the employment of multiple LT-AIN layers inserted between high-temperature GaN which was previously demonstrated to be effective with GaN grown by MOCVD, as described by M. Iwaya et al., Jpn. J Appl. Phys., Vol. 37, p. L316 (1998), which is incorporated herein by reference. In our experiments, LT-AIN interlayers were employed in MBE growth in order to reduce the dislocation density. FIG. 11 shows the cross-sectional TEM image of a GaN sample grown with two LT-AIN interlayers. The dislocation density was estimated by counting the number of dislocations along the cross-section and taking the square of the linear density. In this image, the screw and mixed dislocations (g=<0002>) were found to be reduced from ˜2×10⁹ cm⁻² in the GaN grown after the first AN nucleation layer to ˜5×10⁸ cm⁻² close to the top of the 0.6 μm film grown following the LT-AIN layers. The edge type dislocations were reduced by about a factor of two from 6×10^{9 cm}⁻² to 3×10⁹ cm⁻².

### In-situ Control of the Growth Rate

Several groups have reported on the use of reflection high energy electron diffraction (RHEED) intensity oscillations to monitor the growth rate during GaN, AlGaN and InGaN IB growth. However, RHEED intensity oscillations have only been reported for growths carried out at relatively low temperatures (T_{growth}<600° C.). In addition, the RHEED intensity oscillations usually persist only for the first few monolayers of growth. In contrast, the oscillations of the pyrometer signal due to the interference effect persist throughout the entire growth run. This pyrometric interference technique has been used in the prior art to monitor in-situ the growth rate of GaAs/AlₓGa₁₋ₓAs. The growth rate is related to the oscillation period by the simple relation given in equation (1) below:

$$G = \frac{1}{T} \times \frac{λ}{2} \times \frac{1}{n \cdot cos θ} \qquad ( 1 )$$

where T is the oscillation period (in seconds), λ is the wavelength of the pyrometer (940 nm), n is the refractive index of the material at the growth temperature and θ is the effective detection angle relative to the substrate normaL FIG. 12 shows a plot of the pyrometer oscillations as a function of growth time. Equation (1) can be rewritten as follows:

$$G = \frac{D}{T} \qquad ( 2 )$$

where D is defined as the effective thickness per oscillation. The calculated value of D is 205.6 nm (using n(940 nm)=2.35 and θ=13.4°) which differs by 6% from the empirically determined value of 193.5 nm for GaN. The difference between the calculated and measured values of D can be attributed to the uncertainty in the refractive index of GaN at high temperature. To obtain the empirical value of D, a thick layer of GaN was first grown and the number of oscillations recorded. The total thickness of the sample was then measured ex-situ by cross-sectional SEM and divided by the number of oscillations. Once D is known, the growth rate can be obtained in subsequent growth runs simply by measuring the oscillation period (in seconds). The variation in the oscillation period is a direct indication of the change in growth rate.

In an effort to evaluate the precise control of the growth rate, a series of growths were performed in which four quantum wells with thicknesses of 10, 20, 30 and 40 Å were deposited. The growth rate was obtained in-situ by monitoring the oscillations of the pyrometer signal during the growth of a thick GaN layer (˜0.6 μm) before the growth of the quantum wells. The cross-sectional TEM image of the four quantum wells separated by Al_{0.8}Ga_{0.2}N barriers is shown in FIG. 13. In this case, the thickness of each of the AlGaN barriers was 50 Å. The low temperature (4 K) photoluminescence of a similar set of quantum wells with Al_{0.2}Ga_{0.8}N barriers it was measured and shown in FIG. 14. There are four individual peaks at 3.62, 3.52, 3.45 and 3.37 eV attributed to the four quantum wells in the order of increasing thickness. In addition, a peak (3.494 eV) that originates from the underlying thick GaN layer was also observed along with two LO-phonon related peaks. The LO-phonon peaks are not of equal spacing due to the fact that they are a superposition of phonon peaks from mainly the 30 and 40 Å quantum wells. A multiple peak Gaussian-fit of the peaks using a phonon energy of 88 meV, including contributions of LO-phonons from the 30 and 40 Å wells, provides a good fit to the experimental data. The increasing red-shift observed for larger well widths (30 and 40 Å) is attributed to the large built-in electric field due to spontaneous and piezoelectric polarization in GaN/AlGaN heterostructures. The well-resolved PL peaks are an indication that the quantum wells are of high quality. The red-shift of the PL transition energy is in agreement with the calculated values reported by others. In addition, a similar PL spectrum has been observed in the prior art for GaN quantum wells (10, 20 and 30 Å) with Al_{0.24}Ga_{0.76}N barriers.

### Intersubband Absorption in GaN/AIGaN Quantum Wells

FIG. 15 shows a cross-sectional TEM image of a 10-period superlattice with 20 Å GaN wells separated by 60 Å A_{0.65}Ga_{0.35}N barriers. This was one of the samples where a strong, clear intersubband absorption peak was seen. The thicknesses of the well and barrier layers measured from the image were in excellent agreement with the intended growth thicknesses. The interface between the well and barrier layers was abrupt and the roughness along the interface was estimated to be about one monolayer. Superlattice samples with higher AN mole fraction (80%) in the barriers have also been characterized with cross-sectional TEM and similar results were observed in terms of layer uniformity and interface roughness. X-ray difraction measurements around the (0002) Bragg peak show distinct higher-order superlattice peaks up to the third-order. Since the AlGaN barrier layers were thin (total thickness of 660 Å for 11 layers), they were expected to be pseudomorphic to the underlying thick GaN layer, as observed by others.

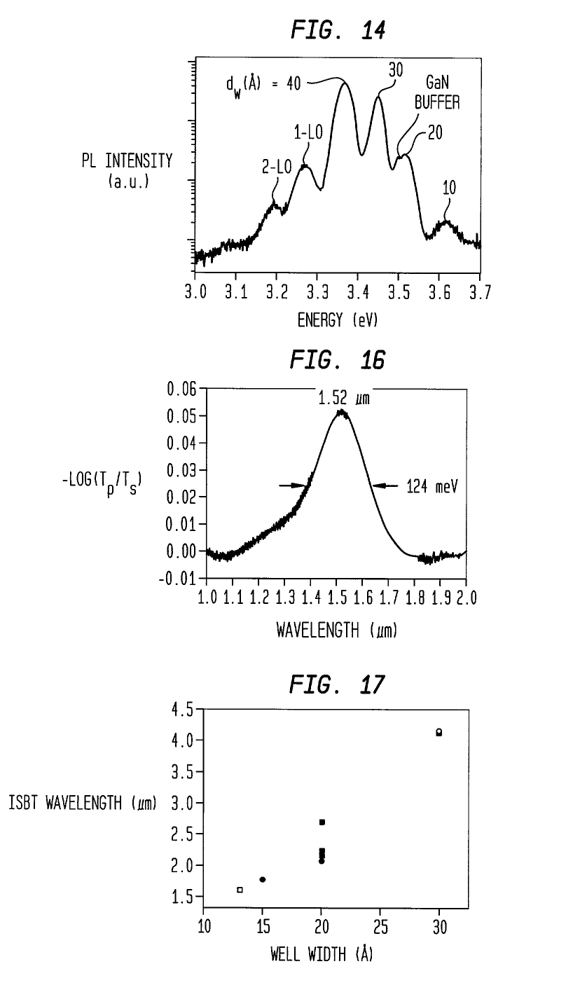

By changing the GaN quantum well width and the AlGa barrier height of the superlattices, we have observed ISB absorption in the wavelength range of 1.52 to 4.2 μm. FIG. 16 shows the spectrum of ISB absorption at 1.52 μm for a sample with 10 periods of 13 Å GaN well and 60 Å Al_{0.85}Ga_{0.15}N barrier. The ISB nature of the transition was confirmed by the fact that absorption was observed for p-polarized but not for s-polarized light. The spectrum shown was normalized by taking the ratio of the p-polarized to s-polarized absorption spectra and subtracting the background absorption from the sapphire substrate. The full-width at half maximum of the absorption peak is 124 meV.

The variation of the ISB absorption peak wavelength as a function of the GaN well width is shown in FIG. 17. The absorption peak shifted to shorter wavelengths as the well width was decreased. This is expected due to the increased separation of the subband levels with decreasing well width. The trend towards shorter absorption wavelengths was also seen for increasing the AlN mole fraction in the barrier layers, which translates to an increase in the barrier height. The role of the large built-in electric field also has to be considered for wurtzite III-nitrides. As discussed earlier, the built-in electric field affects the interband transition of Ga/AlGa quantum wells by inducing a red-shift in the transition energy (quantum-confined Stark effect). This is due to the electric field-induced triangular profile at the bottom of the conduction band and at the top of the valence band in the quantum well. For ISB transitions, the field in the barrier rather than the well plays a larger role in determining the peak transition energy. Particularly for narrow wells, the first subband level is high enough that it is not affected by the triangular profile at the bottom of the conduction band. The AlGaN barrier also has a triangular profile due to the large field and therefore, electrons in the second subband have an increased probability of tunneling to the three-dimensional density of states, which results in a lower “effective” barrier. The component of the built-in field due to piezoelectric polarization can be engineered by growing the superlattice on a thick AlₓGa₁₋ₓN instead of a GaN layer. In the case where the GaN/AlGaN superlattices are grown on thick GaN, the AlGaN barriers are under tensile strain. The tensile strain in the barriers can be eliminated by growing the superlattices on a thick AlₓGa₁₋ₓN layer with matching composition as that of the barrier. As a proof of concept, we have grown two sets of samples with identical superlattices on top of either thick GaN or AlGaN layers. In FIG. 17, the two data points marked by closed and open triangles are for GaN/Al_{0.85}Ga_{0.15}N superlattice (10 periods) grown on Al_{0.65}Ga_{0.35}N and GaN/Al_{0.65}Ga_{0.35}N superlattice (10 periods) grown on Al_{0.5}Ga_{0.5}N, respectively. A shift to shorter intersubband transition wavelength was observed for both sets of samples compared with similar superlattices grown on GaN. This is a clear manifestation of the influence of the built-in electric field on the ISB transition.

Summary of Example II

We have demonstrated ISB absorption at wavelengths as short as 1.52 μm for the first time in high-quality GaN/AlGaN superlattices grown by MBE. The threading dislocation density in the films was reduced by inserting low-temperature AlN layers during the initial stages of growth. Using in-situ monitoring of the growth rate by pyrometric interferometry, superlattice structures with precise thicknesses were grown. The interfaces between the well and barrier layers were found to be abrupt by cross-sectional TEM. The absorption peak shifted to shorter wavelengths with a reduction in the well width and increase in the barrier height. Preliminary investigations on the effect of the built-in electric field on the ISB transition confirmed that a blue-shift of the transition wavelength could be achieved by reducing the tensile stress in the AlGaN barrier. The successful demonstration of intersubband absorption at 1.52 μm opens new avenues for the application of III-nitrides to near infrared optoelectronics.

### EXAMPLE III

In this example we describe ISB devices in which the AR QWs included symmetric or asymmetric coupled double quantum wells (DQWs). Multi-pass ISB absorption at room temperature was used to probe the energy levels. We employed degenerate doping to establish a common reference energy level, and show evidence of energy level “anti-crossing” in symmetric DQWs.

TABLE 1
gives an overview of the samples of this study with the nominal
layer thicknesses and AIN-mole fractions of the AlGaN barriers.

| Sample | d_{W1}/d_{B}/d_{W2} (Å)^{a)} | x (AlₓGa₁₋ₓN) | barrier (Å)^{b)} |
|---|---|---|---|
| N306 | 12/10/12 | 0.85-0.90 | 50 |
| N325 | 12/60/20 | 0.85-0.90 | 60 |
| N326 | 12/10/20 | 0.85-0.90 | 60 |
| N362 | 12/10/20 | 0.60-0.65 | SL^{c)} |
| N366 | 12/7/20 | 0.60-0.65 | SL |
| N367 | 9/7/15 | 0.60-0.65 | SL |
| N369 | 12/15/20 | 0.60-0.65 | SL |
| N378 | 20/10/12 | 0.60-0.65 | SL |
| The footnotes in the table are described as follows: ^{a)}This column give the nominal widths of the two QWs, | | | |
| # “W1” and “W2”, and the intermediate barrier, “B”, of the DQWs; underlined layers indicate | | | |
| # the location of intentional doping; ^{b)}This column give the widths of the barrier separating adjacent DQWs; | | | |
| # and ^{c)}All SL-barriers in this column contained 3 QWs, each 7.8 Å wide, separated by 15 Å wide | | | |
| # barriers. | | | |
| All structures were grown by molecular beam epitaxy (MBE) on c-axis sapphire and with AIN buffer layers | | | |
| # and template layers of different thicknesses (typically 0.5-1 μm) and different AIN-mole fractions in | | | |
| # the AlGaN barriers, as described in Example II, above. Some (GaN) template layers were doped with Si to | | | |
| # n ˜ 1 × 10¹⁷ cm⁻³; a control sample with only a doped template was used to exclude | | | |
| # any effect of the latter. Typically 15 RUs were then grown, each RU including a DQW AR separated either by thick | | | |
| # bulk-like AlGaN barriers (Samples N306, N325, and N326) or doped SL barriers (all other samples). The latter | | | |
| # are described in Example I. The DQWs were either directly doped or selectively doped with a carrier density | | | |
| # 1 × 10¹⁹ cm⁻³. The layer structures were capped with few 100 Å of low-doped GaN. | | | |

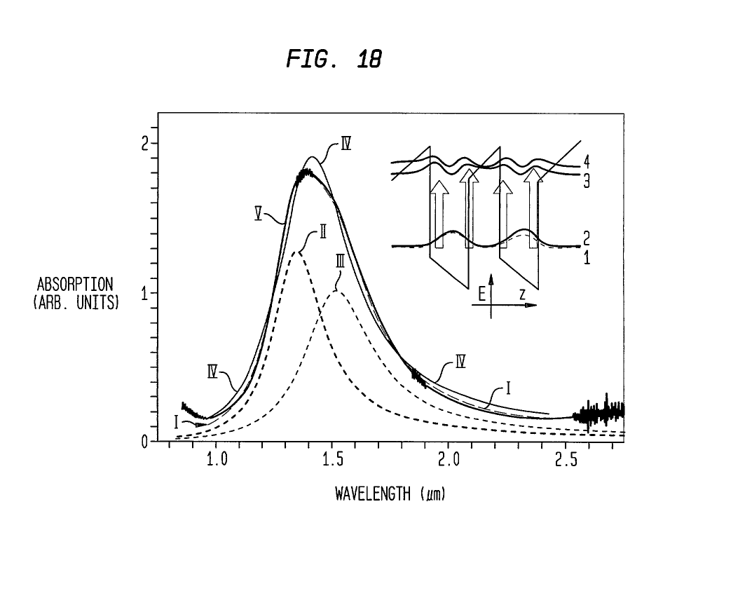

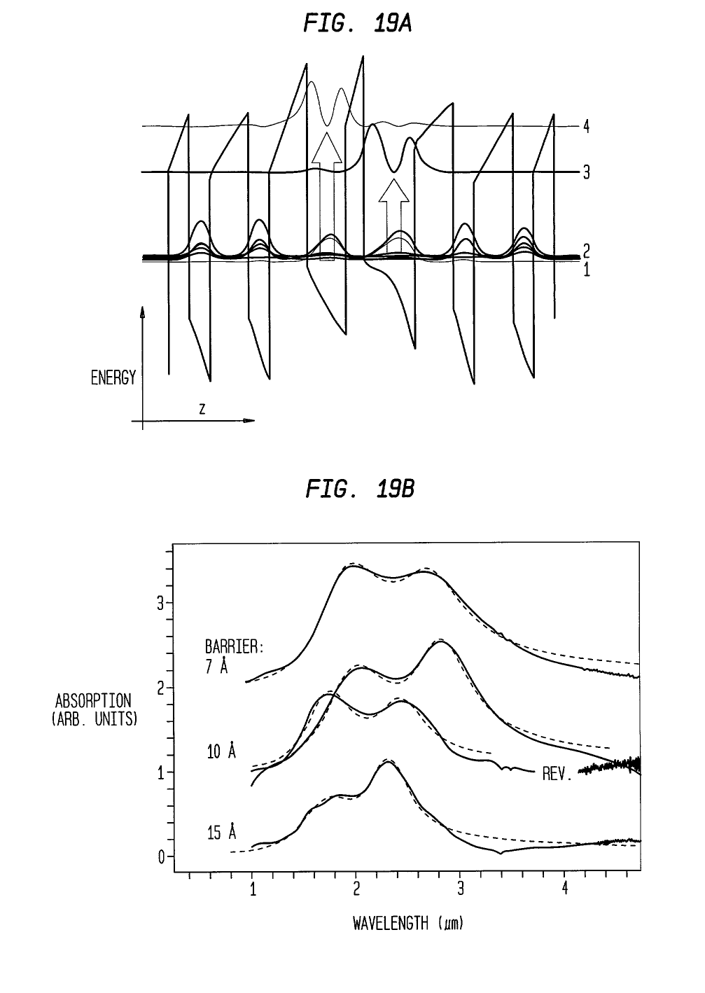

We modeled our structures by iteratively solving Schroedinger's and Poisson's equations; the inset in FIG. 18 and FIG. 19(a) show results of such calculations, where we assumed an intrinsic electric field in the barriers and wells of ±5 MV/cm, respectively. We verified that the result is qualitatively the same and quantitatively within a few percent even if zero electric field is assumed.

In Example I we established that very narrow, <20 Å wide, AR QWs are needed to reach ISB transitions with wavelengths around 1.55 μm. For coupled AR QWs 15 Å and 20 Å thick we calculated ground-state anti-crossing energies of 5, 19, 43, and 131 meV for second barrier region (ire., AlGaN barriers of the SLs) thicknesses of 15, 10, 7, and 3 Å, respectively. In particular, the thickness of these barrier regions where the anti-crossing energy equals the LO phonon energy would be 4.5 Å; ie., approximately 1.5 monolayers. Such thin barriers may be difficult to fabricate due to ubiquitous monolayer thickness fluctuations inherent in the MBE process. However, excited-state level anti-crossing energies can be substantially larger. Similarly, narrower AR QWs also lead to a larger anti-crossing, though in very thin AR QWs only a single energy level may remain confined.

For the above calculation of the anti-crossing energies, we varied the external electric field normal to the AR QW layers and determined the closest energy separation of the first two states of the DQWs. Varying the internal electric fields had essentially the same effect. However, since the latter are not known, degenerate doping of the structures was used to screen them, such that a common Fermi-level was achieved across all AR QWs. This design results in full anti-crossing of the AR QW ground-states independent of the intrinsic electric fields, as shown in FIGS. 18 and 19(a). We estimated Fermi-energies for the various samples of 100-200 meV.

The experimental procedures for the ISB absorption are described by Gmachl et al., Appl. Phys. Lett., Vol. 77, No. 3 , pp. 334-336 (July 2000), which is incorporated herein by reference. Although in FIGS. 18-20 we show absorption in arbitrary units, we note that the absorption signal was quite strong, up to 50% for the ˜5 mm long multi-pass samples.

FIG. 18 shows the results for the symmetric DQW, Sample N306. The experimentally obtained absorption is depicted as a function of wavelength. Usually such absorption traces, when plotted versus energy, can be fitted well with Lorentzian line-shape functions. In the particular case of FIG. 18, however, a least-square fit employing only a single Lorentzian curve did not provide a satisfactory result compared to a fit using the sum of two Lorentzians. The peak transition energies are 816 meV (1.52 μm) and 920 meV (1.35 μm), with a peak separation of 104 meV, which is also the value expected from the band structure calculation shown in the inset. This measurement served as an example for excited-state anti-crossing. The ground-state anti-crossing energy was calculated as 21 meV, which is much smaller than the energy width of the transitions, such that we treated the two states as being essentially indistinguishable.

FIG. 19(a) displays a portion of the conduction band energy diagram of a sample with asymmetric DQWs, a 7 Å barrier in each DQW, and SL barriers between adjacent DQWs. The moduli squared of the wavefunctions are shown, and the levels involved in the optical transitions are marked 1, 2, 3, and 4. Levels 1 and 2 are anti-crossed by 34 meV, again a small value compared to the broadening of each transition, which we cannot resolve in our measurements. FIG. 19(b) shows the measured absorption of four variations of the asymmetric DQWs of FIG. 19(a). In all cases, both transitions into the excited states 3 and 4 were well resolved, and we fitted the experimental curves (solid lines) again with the sum of two Lorentzians (dashed curves). The variations between the curves are attributed to fluctuations in layer thicknesses between samples. In fact, invoking a previously obtained calibration of peak wavelength versus QW thickness as described in Example II, all four curves can be overlapped precisely (within experimental error).

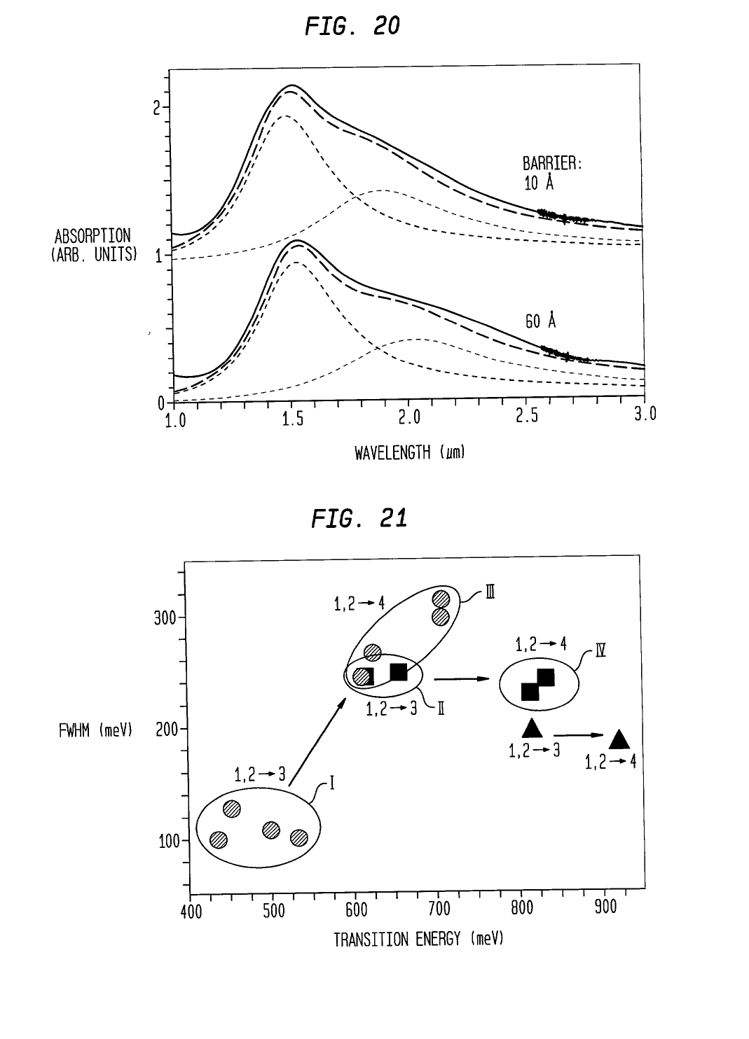

FIG. 20 shows a comparison of a device having asymmetric DQWs with an AR barrier thickness of 10 Å (Sample N326) between the coupled AR QWs and one having similar QWs, but all isolated by 60 Å bulk-like barriers (Sample N325). From the experiments discussed in FIGS. 18 & 19 we do not expect any effect from the 10 Å thin barrier, which is evidently confirmed by the data shown in FIG. 20. (A coupling effect across a 10 Å wide barrier was observed for the symmetric DQW, where the excited states were brought into anti-crossing by energetically aligning the ground-states.) Two absorption lines, centered at 1.5 μm and 2.0 μm, corresponding to the two isolated QWs were distinguished.

A sample (N367, not shown) having asymmetric DQWs including an only 9 Å wide AR QW, displayed only a single absorption feature, consistent with the fact that in such a narrow well, with ˜0.65 AlN-mole fraction AlGaN barriers, no excited state is confined.

So far, only the peak transition energy data have been discussed. However, also the fill width at half maximum (FWHM) of the observed absorption features carries valuable information. FIG. 21 displays the FWHM as a function of the peak transition energy for the various samples. The data are grouped by sample type and AlN-mole fraction of the AlGaN barriers. As can be seen, absorption into the higher lying level 4 was significantly broadened compared to absorption into level 3 in samples with only ˜0.65 AlN-mole fraction AlGaN barriers. Samples with ˜0.90 AlN-mole fraction AlGaN barriers showed no significant difference in the FWHM values for absorption into higher and lower lying states. We interpret this as a loss of confinement for the upper state 4 in the lower AlN-mole fraction material. The generally larger FWHM values of the ˜0.90 AlN-mole fraction samples can be explained by their being doped inside the QWs rather than selectively doped in the SLs, as was the case with the ˜0.65 AlN-mole fraction samples.

It is to be understood that the above-described arrangements are merely illustrative of the many possible specific embodiments that can be devised to represent application of the principles of the invention. Numerous and varied other arrangements can be devised in accordance with these principles by those skilled in the art without departing from the spirit and scope of the invention. In particular, although we have described various embodiments of our invention as illustratively having GaN QWs with AlGaN barriers, other materials are also suitable such as InGaN QWs with AlGaN barriers. The use of InₓGa₁₋ₓN QWs is advantageous since it provides a larger maximum band offset than GaN (a maximum of about 3 eV for x=0; i.e., for ISN QWs).

What is claimed is:

1. An intersubband optical device comprising
first quantum well interior regions having upper and lower energy states between which intersubband transitions take place; and
superlattice barrier regions interposed between said first quantum well interior regions so as to produce upper and lower minibands of energy levels, said superlattice barrier regions including second barrier regions and second quantum well interior regions, said second quantum well interior regions being interposed between said second barrier regions, said first quantum well interior regions and said super lattice barrier regions being configured to produce an energy gap between said upper and lower states that is larger than the energy of an approximately 1.7 μm wavelength photon.

2. The invention of claim 1 wherein said second quantum well interior regions are narrower than said first quantum well interior regions.

3. The invention of claim 2 wherein said first quantum well interior regions are at least 1.5 times as wide as said second quantum well interior regions.

4. The invention of claim 2 wherein said one of said first and second quantum well interior regions comprises GaN.

5. The invention of claim 2 wherein said barrier regions comprise a compound of AlₓGa₁₋ₓN.

6. The invention of claim 5 wherein x is less than about 0.85.

7. The invention of claim 5 wherein x is less than about 0.70.

8. The invention of claim 5 wherein said first quantum well interior regions are least 2 times as wide as said second quantum well interior regions.

9. The invention of claim 2 wherein said first quantum well interior regions and said superlattice barrier regions are configured to position a Fermi level below said lower miniband of said superlattice barrier regions and above said lower energy state of said first quantum well interior regions.

10. The invention of claim 2 wherein said first quantum well interior regions are doped with an n-type impurity to a concentration of about 0.1-10×10²⁰ cm⁻³.

11. The invention of claim 2 wherein said second quantum well interior regions are doped with an n-type impurity to a concentration of about 0.1-10×10²⁰ cm⁻³.

12. The invention of claim 2 wherein said quantum well regions comprise a compound of InₓGa₁₋ₓN.

13. An electro-optical apparatus comprising
a semiconductor body having a stacked, multilayered construction, said body including first quantum well interior regions having upper and lower energy states between which intersubband transitions take place, and superlattice barrier regions interposed between said first quantum well interior regions so as to produce upper and lower minibands of energy levels within said superlattice barrier regions, said superlattice barrier regions including second barrier regions and second quantum well interior regions, said second quantum well interior regions being interposed between said second barrier regions, said first quantum well interior regions and said super lattice barrier regions being configured to produce an energy gap between said upper and lower states that is larger than the energy of an approximately 1.7 μm wavelength photon, and
means for applying and/or extracting energy from said body.

14. The invention of claim 13 wherein said applying and/or extracting means comprises ohmic contacts electrically coupled to said body.

15. The invention of claim 13 wherein said applying means includes means for optically pumping said body.

16. An intersubband optical device comprising
a core region including a multiplicity of repeat units,
each of said repeat units including a first barrier region and a quantum well active region disposed adjacent thereto, characterized in that
each of said quantum well active regions has upper and lower energy states separated by an energy greater than the energy of a 1.7 μm photon, and
said barrier region comprises a superlattice configured to have minibands separated by minigaps that confine electrons to said upper state.

17. The invention of claim 16 wherein each said superlattice comprises a multiplicity of second quantum well regions and second barrier regions interleaved with one another, and at a least one of said second quantum well regions is doped such that electrons are transported from said at least one second quantum well region into an active quantum well region.

18. The invention of claim 17 wherein said active region quantum wells comprise GaN, said second quantum well regions comprise Al_{y}Ga_{1-y}N and said second barrier regions comprise AlₓGa₁₋ₓN.

19. The invention of claim 18 wherein 0≦y≦0.2 and x>0.65 approximately.

20. The invention of claim 18 wherein said quantum well active regions and said second barrier regions are essentially undoped and said second quantum well regions are doped n-type.

21. The invention of claim 18 further including a substrate on which said core region is formed and a transition zone disposed between said substrate and said core region, said transition zone including a buffer region disposed on said substrate and a template region disposed on said buffer region, thereby to redistribute charge accumulated at the interfaces between said quantum well active regions and said first barrier regions so as to increase the built-in electric field in said quantum well active regions and to decrease the built-in electric field in said second barrier regions.

22. The invention of claim 21 wherein said buffer region comprises relatively thin, high-temperature AlN, said template region comprises relatively thick, high-temperature GaN or Al_{z}Ga_{1-z}N, and at least two separated, relatively thinner, low-temperature AlN layers embedded in said template region.

23. The invention of any one of claims 16-22 further including means for absorbing in said core region an optical photon having a wavelength shorter than about 1.7 μm so as to generate a photocurrent, and means for utilizing said photocurrent.

24. The invention of any one of claims 16-22 further including means for applying pump energy to said core region, thereby to cause said actives to emit optical photons having a wavelength shorter than about 1.7 μm, and means for utilizing said photons.

25. The invention of claim 16 wherein said quantum well active regions and said first barrier regions are configured to position a Fermi level below said lower miniband of said first barrier regions and above said lower energy state of said active well interior regions.

26. The invention of claim 16 wherein said quantum well active regions comprise a compound of InₓGa₁₋ₓN.
